(19) United States
(12) Patent Application Publication
(10) Pub. No.: US 2026/0100720 A1
(43) Pub. Date: Apr. 9, 2026

(54) SIGNAL CONVERSION DEVICE AND BIT ERROR RATE TEST METHOD

(71) Applicant: REALTEK SEMICONDUCTOR CORPORATION, HSINCHU (TW)

(72) Inventor: MING-CHUNG HUANG, HSINCHU (TW)

(21) Appl. No.: 19/316,634

(22) Filed: Sep. 2, 2025

(30) Foreign Application Priority Data
Oct. 4, 2024 (TW) 113137982

(51) Int. Cl. H03M 1/12; H03M 1/06

(52) U.S. Cl. CPC H03M 1/126; H03M 1/0651

(57) ABSTRACT

A bit error rate testing method includes: sampling, by an analog-to-digital converter circuit, a symmetric signal to generate output digital codes; identifying a starting digital code in the output digital codes; storing the starting digital code and first digital codes, which follow the starting digital code in the output digital codes, into a first register circuit in an order as second digital codes, in which the starting digital code and the first digital codes correspond to one cycle of the symmetric signal; storing the starting digital code and the first digital codes into a second register circuit in a reversed order; shifting the starting digital code and the first digital codes in the second register circuit to generate third digital codes; and determining a bit error rate of the analog-to-digital converter circuit according to a difference between a corresponding second digital code and a corresponding one third digital code.

### BACKGROUND OF THE INVENTION

### 1. Field of the Invention

The present disclosure relates to a signal conversion device, especially to a signal conversion device and a bit error rate testing method that are able to test an analog-to-digital converter circuit without using an additional threshold voltage.

### 2. Description of Related Art

The bit error rate is often employed to evaluate the performance of an analog-to-digital signal converter. In some related approaches, two consecutive digital codes generated by the analog-to-digital signal converter are utilized to determine whether bit errors occur. For example, a difference between the two digital codes is compared with a threshold voltage. If the difference is greater than the threshold voltage, it is determined that at least one of the two digital codes includes a bit error. However, in the aforementioned approaches, if both consecutive digital codes include error ( for example, if both digital codes incorrectly increase), the difference between the two digital codes may not exceed the threshold voltage. As such, these two digital codes including bit errors may not be detected, which leads to inaccurate evaluation of the bit error rate. Furthermore, in the aforementioned approaches, the threshold voltage needs to vary with the frequency of the input signal. For example, when the input signal frequency increases, the interval between two consecutive sampling points becomes larger, and therefore, the threshold voltage needs to be increased. On the other hand, if the difference between two consecutive digital codes is configured within a predetermined range (for example, less than or equal to one least significant bit), the frequency of the input signal will be limited.

### SUMMARY OF THE INVENTION

In some embodiments of the present disclosure, one of the objectives of the present disclosure is, but not limited thereto, to provide a signal conversion device and a bit error rate testing method that area able to test an analog-to-digital converter circuit without using an additional threshold voltage, so as to improve the deficiencies of the prior art.

In some aspects of the present disclosure, a bit error rate testing method includes the following operations: sampling, by an analog-to-digital converter circuit, a symmetric signal to generate a plurality of output digital codes; identifying a starting digital code in the plurality of output digital codes; storing the starting digital code and a plurality of first digital codes, which follow the starting digital code in the plurality of output digital codes, into a first register circuit in a first order as a plurality of second digital codes, wherein the starting digital code and the plurality of first digital codes correspond to one cycle of the symmetric signal; storing the starting digital code and the plurality of first digital codes into a second register circuit in a second order, wherein the second order is opposite to the first order; shifting the starting digital code and the plurality of first digital codes in the second register circuit to generate a plurality of third digital codes; and determining a bit error rate of the analog-to-digital converter circuit according to a difference between a corresponding one of the plurality of second digital codes and a corresponding one of the plurality of third digital codes.

In some aspects of the present disclosure, a signal conversion device includes an analog-to-digital converter circuit, register circuits, and at least one control circuit. The analog-to-digital converter circuit is configured to sample an input signal according to a symmetric signal to generate a plurality of output digital codes. The register circuits includes a first register circuit and a second register circuit. The at least one control circuit is configured to: identify a starting digital code in the plurality of output digital codes; store the starting digital code and a plurality of first digital codes, which follow the starting digital code in the plurality of output digital codes, into the first register circuit in a first order as a plurality of second digital codes, wherein the starting digital code and the plurality of first digital codes correspond to one cycle of the symmetric signal; store the starting digital code and the plurality of first digital codes into the second register circuit in a second order, wherein the second order is opposite to the first order; shift the starting digital code and the plurality of first digital codes in the second register circuit to generate a plurality of third digital codes; and determine a bit error rate of the analog-to-digital converter circuit according to a difference between a corresponding one of the plurality of second digital codes and a corresponding one of the plurality of third digital codes.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates a schematic diagram of a signal conversion device according to some embodiments of the present disclosure.

FIG. 2 illustrates a flowchart illustrating a bit error rate testing method according to some embodiments of the present disclosure.

FIG. 3A illustrates a flowchart illustrating detailed steps corresponding to a portion of the operations in FIG. 2 according to some embodiments of the present disclosure.

FIG. 3B illustrates a waveform diagram of the symmetric signal being an even function signal according to some embodiments of the present disclosure.

FIG. 3C illustrates a schematic diagram illustrating the register circuit and the register circuit in FIG. 1 performing operations of FIG. 2, respectively, according to some embodiments of the present disclosure.

FIG. 3D illustrates a schematic diagram illustrating the register circuit of FIG. 1 performing operation of FIG. 2 according to some embodiments of the present disclosure.

FIG. 4A illustrates a flowchart illustrating detailed steps corresponding to a portion of the operations in FIG. 2 according to some embodiments of the present disclosure.

FIG. 4B is a waveform diagram of the symmetric signal being an odd function signal according to some embodiments of the present disclosure.

### DETAILED DESCRIPTION OF THE PREFERRED EMBODIMENTS

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification. In this document, the term “coupled” may also be termed as “electrically coupled,” and the term “connected” may be termed as “electrically connected.” “Coupled” and “connected” may mean “directly coupled” and “directly connected” respectively, or “indirectly coupled” and “indirectly connected” respectively. “Coupled” and “connected” may also be used to indicate that two or more elements cooperate or interact with each other. In this document, the term “circuitry” may indicate a system implemented with at least one circuit, and the term “circuit” may indicate an object, which is formed with one or more transistors and/or one or more active/passive elements based on a specific arrangement, for processing signals.

As used herein, the term "and/or" includes any and all combinations of one or more of the associated listed items. Although the terms “first,” “second,” etc., may be used herein to describe various elements, these elements should not be limited by these terms. These terms are used to distinguish one element from another. For example, a first element may be termed a second element, and, similarly, a second element may be termed a first element, without departing from the scope of the embodiments. For ease of understanding, similar/identical elements in various figures are designated with the same reference number.

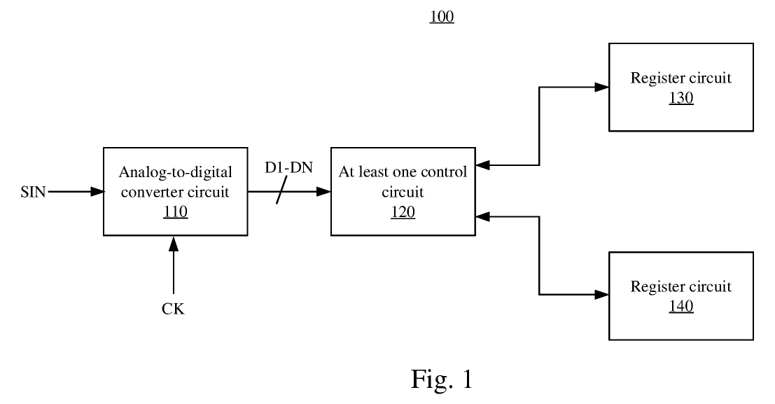

FIG. 1 illustrates a schematic diagram of a signal conversion device 100 according to some embodiments of the present disclosure. The signal conversion device 100 includes an analog-to-digital converter circuit 110, at least one control circuit 120, a register circuit 130, and a register circuit 140. The analog-to-digital converter circuit 110 is configured to sample a symmetric signal SIN according to a clock signal CK to generate output digital codes D1 to DN. In different embodiments, the analog-to-digital converter circuit 110 may be various types of analog-to-digital converters, such as, but not limited to, a pipeline analog-to-digital converter, a successive approximation register analog-to-digital converter, a delta-sigma analog-to-digital converter, a digital slope analog-to-digital converter, and the like.

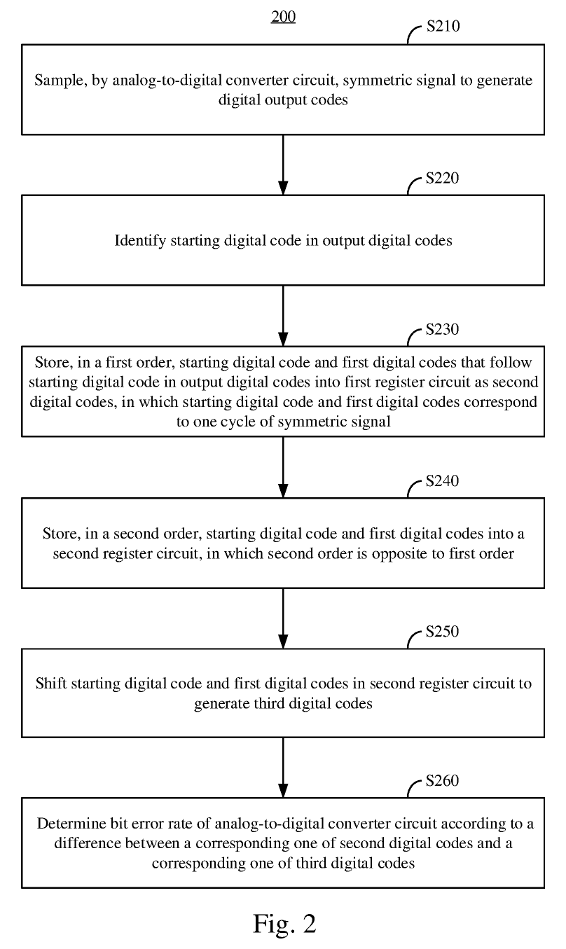

In some embodiments, the at least one control circuit 120 may perform operations in FIG. 2 to determine a bit error rate of the analog-to-digital converter circuit 110. In some embodiments, the at least one control circuit 120 may be implemented with at least one microcontroller circuit having computing capability and may be integrated with the other circuits in FIG. 1 as an integrated circuit. Alternatively, in other embodiments, the at least one control circuit 120 may be implemented with an external device and/or external testing tool and cooperate with the other circuits in FIG. 1 to perform operations in FIG. 2. For ease of illustration and understanding, the related operations of the signal conversion device 100 will be described with reference to multiple figures below.

FIG. 2 illustrates a flowchart illustrating a bit error rate testing method 200 according to some embodiments of the present disclosure. In operation S210, a symmetric signal is sampled by the analog-to-digital converter circuit to generate digital output codes. For example, as shown in FIG. 1, the analog-to-digital converter circuit 110 may sample the symmetric signal SIN according to a clock signal CK to generate digital codes D1 to DN. In some embodiments, the sampling frequency of the analog-to-digital converter circuit 110 (which corresponds to the frequency of the clock signal CK) may be a positive integer multiple of the frequency of the symmetric signal SIN. As a result, the analog-to-digital converter circuit 110 may be configured for coherent sampling. In some embodiments, the symmetric signal SIN may be a signal with waveform symmetry. In some embodiments, the symmetric signal SIN may be an even function signal or an odd function signal.

In operation S220, a starting digital code in the output digital codes is identified. In operation S230, the starting digital code and first digital codes that follow the starting digital code in the output digital codes are stored into a first register circuit in a first order as second digital codes, in which the starting digital code and the first digital codes correspond to one cycle of the symmetric signal. In operation S240, the starting digital code and the first digital codes are stored into a second register circuit in a second order, in which the second order is opposite to the first order. In operation S250, the starting digital code and the first digital codes in the second register circuit are shifted (for example, shifted by one data point) to generate third digital codes. In operation S260, a bit error rate of the analog-to-digital converter circuit is determined according to a difference between a corresponding one of the second digital codes and a corresponding one of the third digital codes.

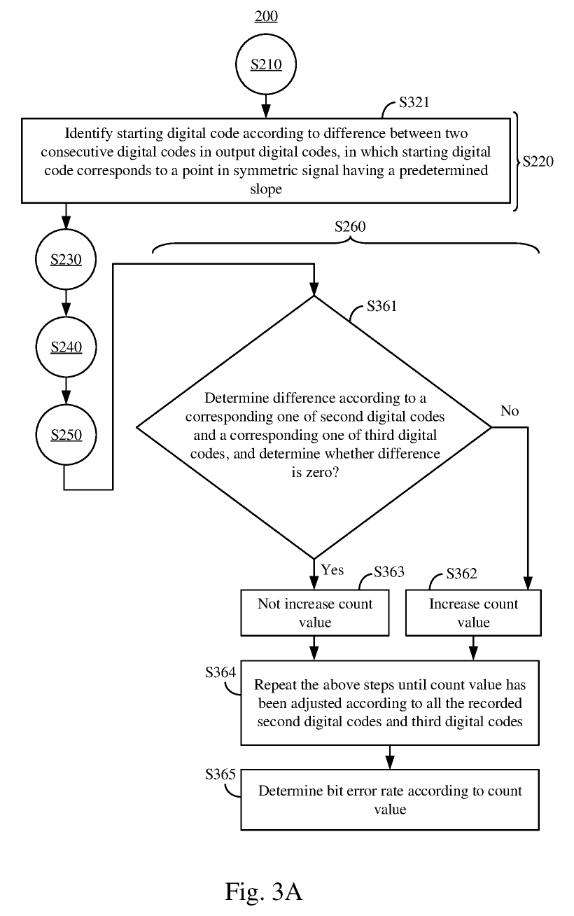

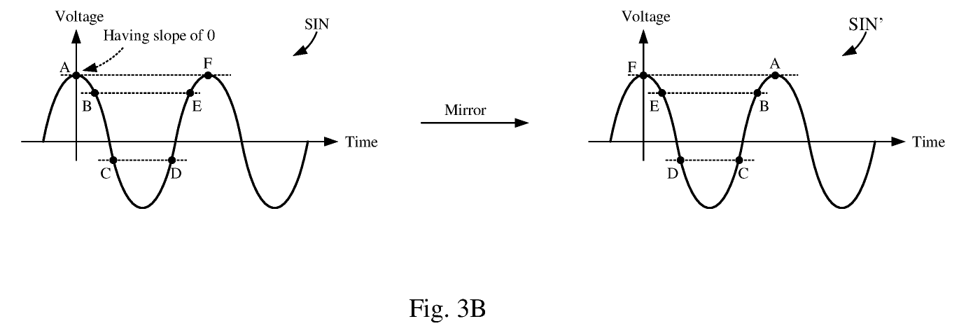

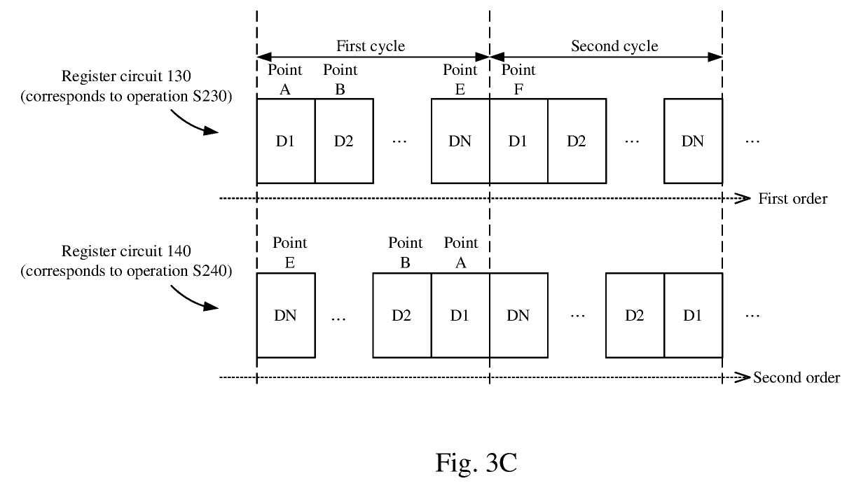

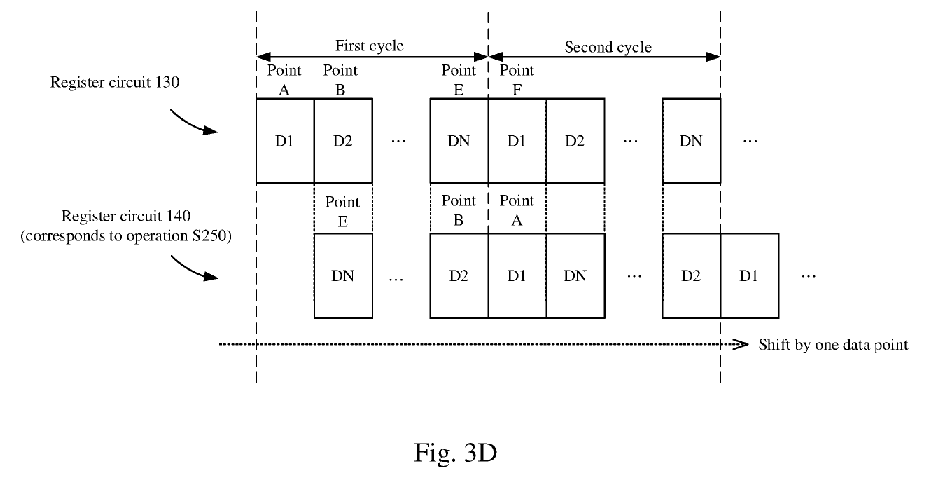

FIG. 3A illustrates a flowchart illustrating detailed steps corresponding to a portion of the operations in FIG. 2 according to some embodiments of the present disclosure. Operation S220 includes step S321. In step S321, the starting digital code is identified according to a difference between two consecutive digital codes in the output digital codes, in which the starting digital code corresponds to a point in the symmetric signal having a predetermined slope. For ease of illustration, reference is now made to FIG. 3B. FIG. 3B illustrates a waveform diagram of the symmetric signal SIN being an even function signal according to some embodiments of the present disclosure. In this example, the symmetric signal SIN is set as an even function signal, such as a cosine wave signal, which is symmetric with respect to the y-axis. For example, as shown in FIG. 3B, the sampling points of one cycle of the symmetric signal SIN by the analog-to-digital converter circuit 110 are points A to F. If the symmetric signal SIN is mirrored with respect to the y-axis, ideally, the value of point F in the mirrored symmetric signal SIN’ will be equal to the value of point A in the original symmetric signal SIN, the value of point E in SIN’ will be equal to that of point B in SIN, and the value of point D in SIN’ will be equal to that of point C in SIN. With this analogy, whether the digital codes generated by the analog-to-digital converter circuit 110 are correct may be determined with above even symmetry characteristics.

To properly utilize the aforementioned characteristic, as described above, the analog-to-digital converter circuit 110 is configured for coherent sampling, and the initial sampling point is set at the starting point of one cycle of the symmetric signal SIN (e.g., point A), where the output digital code generated by the analog-to-digital converter circuit 110 according to the signal sampled at the initial sampling point serves as the starting digital code. As described above, in this example, the symmetric signal SIN is set as an even function signal, the starting point of each cycle corresponds to a point in the symmetric signal SIN having a predetermined slope of 0. As the predetermined slope of 0 indicates minimal signal variation, the at least one control circuit 120 may identify the starting digital code according to the difference between two consecutive digital codes D1 to DN. In some embodiments, the at least one control circuit 120 may sequentially obtain differences between each set of consecutive digital codes D1 to DN, and determine the digital code corresponding to the minimum value in those differences as the starting digital code.

Alternatively, in other embodiments, the at least one control circuit 120 may sequentially obtain differences between each set of consecutive digital codes D1 to DN, and determine whether any two consecutive differences (corresponding to the consecutive output digital codes) exhibit a polarity change, thereby identifying the digital code corresponding to the two consecutive differences as the starting digital code. For example, as shown in FIG. 3B, the ideal starting point is point A, located at the peak of the symmetric signal SIN (i.e., corresponding to the point where the slope is zero). Therefore, assuming that the data point before point A (not shown) corresponds to output digital code Di-1, point A corresponds to output digital code Di, and point B corresponds to output digital code Di+1. The difference between output digital code Di and Di-1 is positive, while the difference between Di+1 and Di is negative. Thus, when the at least one control circuit 120 detects a polarity change (i.e., a transition from positive to negative) in the differences corresponding to the consecutive digital codes Di-1 to Di+1, the at least one control circuit 120 may identify the output digital code Di as corresponding to point A and determine the output digital code Di as the starting digital code.

The above operations for identifying the starting digital code are given for illustrative purposes, and the present disclosure are not limited there to. Depending on the actual circuit configuration (for example, different sampling frequencies or different numbers of sampled data points), various similar operations for identifying the starting digital code are also within the contemplated scope of the present disclosure.

To illustrate operations S230 and S240 in FIG. 2 or FIG. 3A, reference is now made to FIG. 3C. FIG. 3C illustrates a schematic diagram illustrating the register circuit 130 and the register circuit 140 in FIG. 1 performing operations S230 and S240 of FIG. 2, respectively, according to some embodiments of the present disclosure.

As mentioned above, the sampling frequency of the analog-to-digital converter circuit 110 is a positive integer multiple of the frequency of the symmetric signal SIN. For example, the sampling frequency of the analog-to-digital converter circuit 110 may be N times the frequency of the symmetric signal SIN, where N is a positive integer. As such, the analog-to-digital converter circuit 110 may obtain N sampling points in each cycle of the symmetric signal SIN and generate output digital codes D1 to DN accordingly. If output digital code D1 is the aforementioned starting digital code, the at least one control circuit 120 may store output digital code D1 and remaining output digital codes D2 to DN (i.e., the aforementioned first digital codes) corresponding to the same cycle and following output digital code D1 into the register circuit 130 in a first order (corresponding to the sampling order). As shown in FIG. 3C, the register circuit 130 stores the output digital codes D1 to DN in the first order and in cycle order. As a result, the output digital codes D1 to DN in the register circuit 130 may be stored as the aforementioned second digital codes.

Afterwards, the at least one control circuit 120 may store output digital code D1 and the output digital codes D2 to DN following output digital code D1 in the same cycle into the register circuit 140 in a second order (which is opposite to the first order). As shown in FIG. 3C, the register circuit 140 stores the output digital codes DN to D1 in the second order and in cycle order. As a result, the output digital codes D1 to DN in the register circuit 140 may be stored as the aforementioned third digital codes.

It is noted that, in the register circuit 130, the output digital code D1 corresponding to the first cycle corresponds to point A in FIG. 3B, and the output digital code D2 corresponding to the first cycle corresponds to point B in FIG. 3B. Similarly, in the first cycle, the last output digital code DN corresponds to point E in FIG. 3B (not point F). Due to the data recording method of the sampling process, the last one of the output digital codes corresponding to the same cycle is not the starting digital code of the next cycle. Likewise, in the register circuit 140, the output digital code DN corresponding to the first cycle corresponds to point E in FIG. 3B, the output digital code D2 corresponds to point B in FIG. 3B, and the output digital code D1 corresponds to point A in FIG. 3B.

To illustrate operation S250 of FIG. 2 or FIG. 3A, reference is now made to FIG. 3D. FIG. 3D illustrates a schematic diagram illustrating the register circuit 140 of FIG. 1 performing operation S250 of FIG. 2 according to some embodiments of the present disclosure. As described above, the last output digital code in the output digital codes corresponding to the same cycle is not the starting digital code of the next cycle. Therefore, in order to use the even symmetry property shown in FIG. 3B to perform the test, the at least one control circuit 120 may control the register circuit 140 to shift the third digital codes stored in the register circuit 140. Accordingly, the register circuit 140 may shift the output digital codes DN to D1 by one data point to align with the second digital codes stored in the register circuit 130. For example, in the first cycle, the output digital code D2 in the register circuit 130 (corresponding to point B in FIG. 3B) may be aligned with the output digital code DN in the register circuit 140 (corresponding to point E in FIG. 3B), and the output digital code DN in the register circuit 130 (corresponding to point E in FIG. 3B) may be aligned with the output digital code D2 in the register circuit 140 (corresponding to point B in FIG. 3B). Similarly, in the second cycle, the output digital code D1 in the register circuit 130 (corresponding to point F in FIG. 3B) may be aligned with the output digital code D1 in the register circuit 140 (corresponding to point A in FIG. 3B). As a result, the data arrangements in the two register circuits 130 and 140 are able to conform to the even symmetry property, such that the at least one control circuit 120 is able to more efficiently read the above digital codes from the register circuits 130 and 140 to determine the bit error rate.

With continued reference to FIG. 3A, operation S260 of FIG. 2 includes steps S361 to S365. In step S361, a difference is determined according to a corresponding one of the second digital codes and a corresponding one of the third digital codes, and whether the difference is zero is determined. If the difference is not zero, step S362 is performed. If the difference is zero, step S363 is performed. In step S362, a count value is increased. In step S363, the count value is not increased.

For example, as shown in FIG. 3D, the at least one control circuit 120 may subtract the output digital code D2 of the register circuit 130 (corresponding to point B in FIG. 3B) and the output digital code DN of the register circuit 140 (corresponding to point E in FIG. 3B) to generate a difference. Based on the even symmetry property, the value corresponding to point B should be the same as the value corresponding to point E. Therefore, ideally, the difference generated based on the above two digital codes should be zero. If the difference is not zero, it indicates that output digital code D2 (or output digital code DN) has an error. Under this condition, the at least one control circuit 120 may increase the count value by 1. Alternatively, if the difference is zero, it indicates that output digital code D2 and output digital code DN are error-free. Under this condition, the at least one control circuit 120 may not increase the count value. In this manner, the count value can be used to indicate the number of erroneous output digital codes.

In step S364, the above steps are repeated until the count value has been adjusted according to all the recorded second digital codes and third digital codes. In step S365, the bit error rate is determined according to the count value.

For example, the at least one control circuit 120 may repeat the above operations and/or steps to selectively increase the count value according to all the second and third digital codes corresponding to cycles, until the count value has been adjusted by using all the recorded second and third digital codes. As a result, the at least one control circuit 120 may use the adjusted count value to determine the bit error rate of the analog-to-digital converter circuit. In some embodiments, the at least one control circuit 120 may determine the bit error rate according to the ratio between the count value and the total number of second digital codes (or third digital codes) corresponding to the cycles. For example, if the count value is 3 and the total number of second digital codes corresponding to the cycles is 300, the bit error rate may be 3/300. The above values and method for determining the bit error rate are given for illustrative purposes and the present disclosure is not limited thereto.

With the above operations, the at least one control circuit 120 may perform self-comparison based on the output digital codes D1 to DN generated by the analog-to-digital converter circuit 110 (without requiring comparison using an additional threshold voltage) to detect whether there are erroneous digital codes. The above mechanism utilizes symmetry characteristics to compare each digital code individually, thereby avoiding the influence of consecutive erroneous digital codes and ensuring the accuracy of bit error rate calculation.

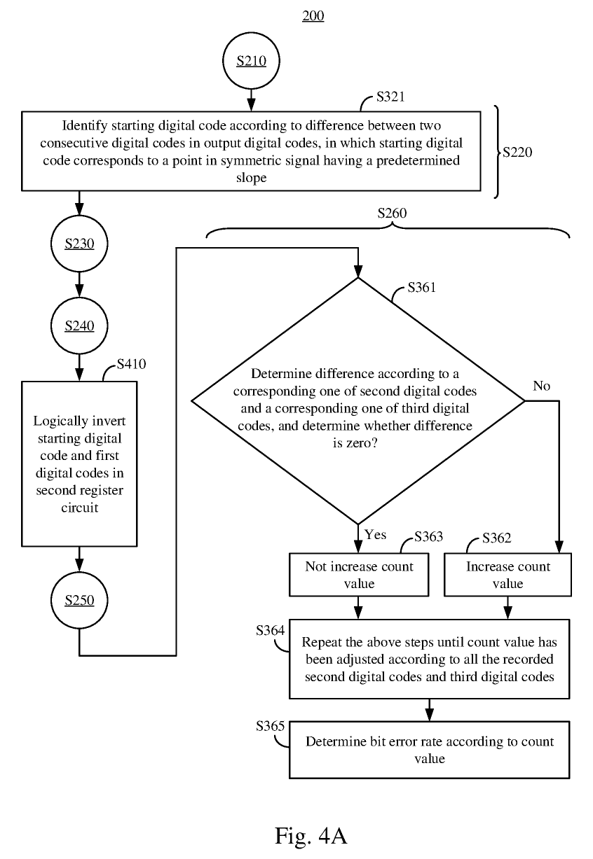

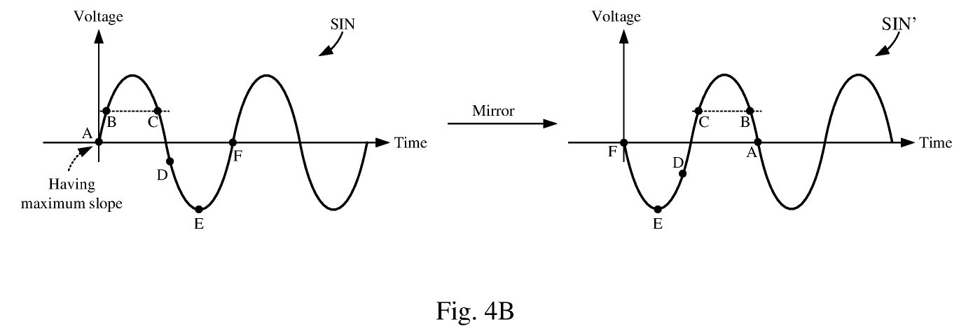

FIG. 4A illustrates a flowchart illustrating detailed steps corresponding to a portion of the operations in FIG. 2 according to some embodiments of the present disclosure. Different from FIG. 3A, in the embodiment corresponding to FIG. 4A, the symmetric signal SIN is an odd function signal. Compared with FIG. 2 or FIG. 3A, the bit error rate testing method 200 of FIG. 4A further includes operation S410. In operation S410, the starting digital code and the first digital codes in the second register circuit are logically inverted. To illustrate operation S410, reference is now made to FIG. 4B. FIG. 4B is a waveform diagram of the symmetric signal SIN being an odd function signal according to some embodiments of the present disclosure. In this example, the symmetric signal SIN is set as an odd function signal, such as a sine wave signal, which is symmetric with respect to the origin. For example, as shown in FIG. 4B, if the symmetric signal SIN is mirrored with respect to the y-axis, the mirrored symmetric signal SIN’ will be inverted with respect to the original symmetric signal SIN (i.e., the phase difference between the two signals are about 180 degrees). Under this condition, the at least one control circuit 120 logically inverts the starting digital code and the first digital codes stored in the register circuit 140 (for example, by multiplying the digital codes by -1). As a result, the logically inverted digital codes can be compared with the digital codes in the register circuit 130 (similar to applying the even symmetry characteristics illustrated in FIG. 3B) to determine the bit error rate.

Furthermore, different from FIGS. 3A and 3B, in this example, when the symmetric signal SIN is an odd function signal, the predetermined slope in step S321 corresponds to the maximum slope of the symmetric signal SIN. For example, as shown in FIG. 4B, the starting point of each cycle (e.g., point A or point F) corresponds to a point in the symmetric signal SIN having the predetermined slope, which is the maximum slope. As the predetermined slope is the maximum slope, it indicates that the signal value changes the most. Therefore, the at least one control circuit 120 may identify the starting digital code according to the difference between two consecutive digital codes D1 to DN. In some embodiments, the at least one control circuit 120 may sequentially obtain differences between consecutive digital codes D1 to DN, and determine the digital code corresponding to the maximum value in these differences as the starting digital code.

The above operations and/or steps in FIGS. 2, 3A, and 4A, include exemplary operations, but those operations are not necessarily performed in the order described above. Operations and/or steps in FIGS. 2, 3A, and 4A, may be added, replaced, changed order, and/or eliminated. Alternatively, operations and/or steps in FIGS. 2, 3A, and 4A, may be performed simultaneously or partially simultaneously as appropriate, in accordance with the spirit and scope of various embodiments of the present disclosure. For example, in other embodiments, operation S410 may be performed after operation S250.

As described above, the signal conversion device and the bit error rate testing method provided in some embodiments of the present disclosure may perform self-comparison according to digital codes generated by the analog-to-digital converter circuit without using an additional threshold voltage, to determine the bit error rate of the analog-to-digital converter circuit. As a result, the influence of consecutive erroneous digital codes can be avoided, thereby improving the accuracy of bit error rate calculation.

Various functional components or blocks have been described herein. As will be appreciated by persons skilled in the art, in some embodiments, the functional blocks will preferably be implemented through circuits (either dedicated circuits, or general purpose circuits, which operate under the control of one or more processors and coded instructions), which will typically comprise transistors or other circuit elements that are configured in such a way as to control the operation of the circuitry in accordance with the functions and operations described herein. As will be further appreciated, the specific structure or interconnections of the circuit elements will typically be determined by a compiler, such as a register transfer language (RTL) compiler. RTL compilers operate upon scripts that closely resemble assembly language code, to compile the script into a form that is used for the layout or fabrication of the ultimate circuitry. Indeed, RTL is well known for its role and use in the facilitation of the design process of electronic and digital systems.

The aforementioned descriptions represent merely the preferred embodiments of the present disclosure, without any intention to limit the scope of the present disclosure thereto. Various equivalent changes, alterations, or modifications according to the claims of the present disclosure are all consequently viewed as being embraced by the scope of the present disclosure.

What is claimed is:

1. A bit error rate testing method, comprising:
sampling, by an analog-to-digital converter circuit, a symmetric signal to generate a plurality of output digital codes;
identifying a starting digital code in the plurality of output digital codes;
storing the starting digital code and a plurality of first digital codes, which follow the starting digital code in the plurality of output digital codes, into a first register circuit in a first order as a plurality of second digital codes, wherein the starting digital code and the plurality of first digital codes correspond to one cycle of the symmetric signal;
storing the starting digital code and the plurality of first digital codes into a second register circuit in a second order, wherein the second order is opposite to the first order;
shifting the starting digital code and the plurality of first digital codes in the second register circuit to generate a plurality of third digital codes; and
determining a bit error rate of the analog-to-digital converter circuit according to a difference between a corresponding one of the plurality of second digital codes and a corresponding one of the plurality of third digital codes.

2. The bit error rate testing method of claim 1, wherein identifying the starting digital code in the plurality of output digital codes comprises:
identifying the starting digital code according to a difference between two consecutive digital codes in the plurality of output digital codes, wherein the starting digital code corresponds to a point in the symmetric signal having a predetermined slope.

3. The bit error rate testing method of claim 2, wherein when the symmetric signal is an even function signal, the predetermined slope is 0.

4. The bit error rate testing method of claim 2, wherein when the symmetric signal is an odd function signal, the predetermined slope is a maximum slope of the symmetric signal.

5. The bit error rate testing method of claim 1, wherein determining the bit error rate of the analog-to-digital converter circuit according to the difference between the corresponding one of the plurality of second digital codes and the corresponding one of the plurality of third digital codes comprises:
increasing a count value if the difference is not zero;
not increasing the count value if the difference is zero; and
determining the bit error rate according to the count value after the count value has been adjusted according to all of the plurality of second digital codes and all of the plurality of third digital codes.

6. The bit error rate testing method of claim 1, further comprising:
logically inverting the starting digital code and the plurality of first digital codes in the second register circuit when the symmetric signal is an odd function signal.

7. The bit error rate testing method of claim 1, wherein shifting the starting digital code and the plurality of first digital codes in the second register circuit to generate the plurality of third digital codes comprises:
shifting the starting digital code and the plurality of first digital codes by one data point to generate the plurality of third digital codes.

8. The bit error rate testing method of claim 1, wherein the symmetric signal is an even function signal or an odd function signal.

9. The bit error rate testing method of claim 1, wherein a sampling frequency of the analog-to-digital converter circuit is a positive integer multiple of a frequency of the symmetric signal.

10. The bit error rate testing method of claim 1, wherein the symmetric signal is a sine wave signal or a cosine wave signal.

11. A signal conversion device, comprising:
an analog-to-digital converter circuit configured to sample an input signal according to a symmetric signal to generate a plurality of output digital codes;
a plurality of register circuits comprising a first register circuit and a second register circuit; and
at least one control circuit configured to:
identify a starting digital code in the plurality of output digital codes;
store the starting digital code and a plurality of first digital codes, which follow the starting digital code in the plurality of output digital codes, into the first register circuit in a first order as a plurality of second digital codes, wherein the starting digital code and the plurality of first digital codes correspond to one cycle of the symmetric signal;
store the starting digital code and the plurality of first digital codes into the second register circuit in a second order, wherein the second order is opposite to the first order;
shift the starting digital code and the plurality of first digital codes in the second register circuit to generate a plurality of third digital codes; and
determine a bit error rate of the analog-to-digital converter circuit according to a difference between a corresponding one of the plurality of second digital codes and a corresponding one of the plurality of third digital codes.

12. The signal conversion device of claim 11, wherein the at least one control circuit is configured to identify the starting digital code according to a difference between two consecutive digital codes in the plurality of output digital codes, and the starting digital code corresponds to a point in the symmetric signal having a predetermined slope.

13. The signal conversion device of claim 12, wherein when the symmetric signal is an even function signal, the predetermined slope is 0.

14. The signal conversion device of claim 12, wherein when the symmetric signal is an odd function signal, the predetermined slope is a maximum slope of the symmetric signal.

15. The signal conversion device of claim 11, wherein the at least one control circuit is configured to perform the following steps to determine the bit error rate:
increase a count value if the difference is not zero;
not increase the count value if the difference is zero; and
determine the bit error rate according to the count value after the count value has been adjusted according to all of the plurality of second digital codes and all of the plurality of third digital codes.

16. The signal conversion device of claim 11, wherein the at least one control circuit is further configured to logically invert the starting digital code and the plurality of first digital codes in the second register circuit when the symmetric signal is an odd function signal.

17. The signal conversion device of claim 11, wherein the at least one control circuit is configured to shift the starting digital code and the plurality of first digital codes by one data point to generate the plurality of third digital codes.

18. The signal conversion device of claim 11, wherein the symmetric signal is an even function signal or an odd function signal.

19. The signal conversion device of claim 11, wherein a sampling frequency of the analog-to-digital converter circuit is a positive integer multiple of a frequency of the symmetric signal.

20. The signal conversion device of claim 11, wherein the symmetric signal is a sine wave signal or a cosine wave signal.
